(19) United States
(12) Patent Application Publication
(10) Pub. No.: US 2021/0276859 A1
(43) Pub. Date: Sep. 9, 2021

(54) A MEMS Package

(71) Applicant: IGNITE, Inc., Minato-Ku Tokyo (JP)

(72) Inventors: Fusao Ishii, Pittsburgh, PA (US); Victor Stone, Pittsburgh, PA (US); Toshitaka Torikai, Sagamihara (JP)

(21) Appl. No.: 17/258,026

(22) PCT Filed: Sep. 26, 2019
(86) PCT No.: PCT/US19/53104

§ 371 Date: Jan. 5, 2021

Related U.S. Application Data
(60) Provisional application No. 62/737,084, filed on Sep. 26, 2018.

(51) Int. Cl. B81B 7/00; G02B 26/08

(52) U.S. Cl. CPC B81B 7/0067; B81B 7/0038; B81B 2207/012; G02B 26/0833; B81B 2201/042; B81B 7/0087

(57) ABSTRACT

A package encapsulating electronic components of one or more Micro-Electro-Mechanical Systems (MEMS) devices has hermetic seal that enables the use of a frame with rough surface. That is, the frame surrounds the components and is affixed to a surface of the substrate with a frame adhering layer. A cover is affixed to the frame with a cover adhering layer. Each of the frame adhering layer and the cover adhering layer comprises a solder layer between metallic adhesion layers. The solder layer comprises reflowed solder balls. The package enables direct contact of a substrate with a heat sink.

### CROSS-REFERENCE TO RELATED APPLICATION

This application claims priority to and the benefit of U.S. Provisional Application Patent Ser. No. 62/737,084, filed Sep. 26, 2018, the entire disclosure of which is hereby incorporated by reference.

### TECHNICAL FIELD

This disclosure relates to a package for enclosing a micro-electro-mechanical systems (MEMS) device.

### BACKGROUND

A MEMS device having one or more mechanical movable elements is desirably packaged to ensure a dry atmosphere within the enclosing package. In some cases, an anti-stiction coating is required for stiction-free operation (e.g., when the mechanical movable element contacts another surface such as a stopper). A cooling system may also be included. A package that can meet these requirements can be a sophisticated and complicated system.

### BRIEF SUMMARY

A Micro-Electro-Mechanical Systems (MEMS) package includes a MEMS device including a substrate on which an electronic circuit is formed, a frame surrounding the electronic circuit and affixed to a surface of the substrate with a frame adhering layer, and a cover affixed to the frame with a cover adhering layer. The cover encapsulates the electronic circuit within the frame, and each of the frame adhering layer and the cover adhering layer comprises a solder layer between at least two metallic adhesion layers. The solder layer comprises reflowed solder balls.

Details of these implementations, and variations in these and other implementations of the teachings herein are described below with reference to the drawing figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a side view of a first example of a MEMS package according to the teachings herein.

FIG. 2 is a perspective view of the MEMS package of FIG. 1

FIG. 3 is an illustration of the results of a soldering step of manufacturing a MEMS package according to the teachings herein.

FIG. 4 is an illustration of the results of a reflow step occurring after the soldering step of FIG. 3.

FIG. 5 is a side view of the MEMS package of FIG. 1 that shows reflected light in relation to a projection lens.

FIG. 6 is a side view of a second example of a MEMS package according to the teachings herein that shows reflected light in relation to a projection lens.

FIG. 7 is a perspective view of the MEMS package of FIG. 6.

FIG. 8 is a side view of the MEMS device of FIG. 1, with the inclusion of a heat sink.

FIG. 9 is a cross-sectional diagram of a MEMS device that can be housed within a MEMS package as described herein.

### DETAILED DESCRIPTION

One way to ensure a dry atmosphere inside a package for a MEMS device (also referred to herein as a MEMS package) is to utilize a hermetic seal. To avoid volatile organic compounds (VOC), the hermetic seal may comprise a metal seal. A metallic adhesion layer for the metal seal may be applied by chemical metallization or vacuum evaporation or sputtering. The flatness of the seal surface should be less than the thickness of the metallic adhesion layer to form a tight seal. However, the thickness of the metallic adhesion layer may be under 5 microns (such as 1 to 2 microns). Achieving a flat seal surface below the thickness of the metallic adhesion layer is difficult and can be expensive. According to the teachings herein, a MEMS package is described that enables a hermetic seal of relatively rough surfaces that can be manufactured inexpensively.

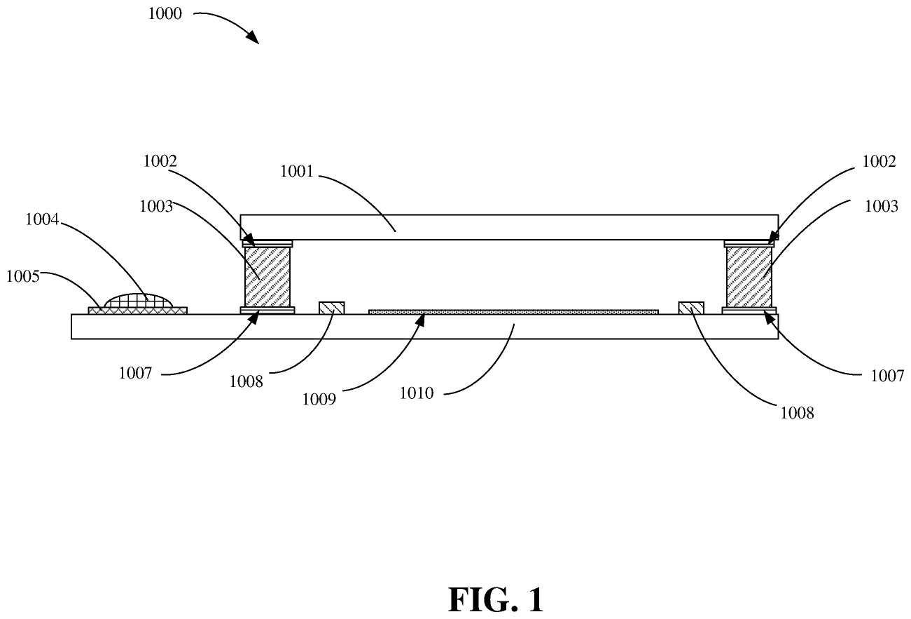

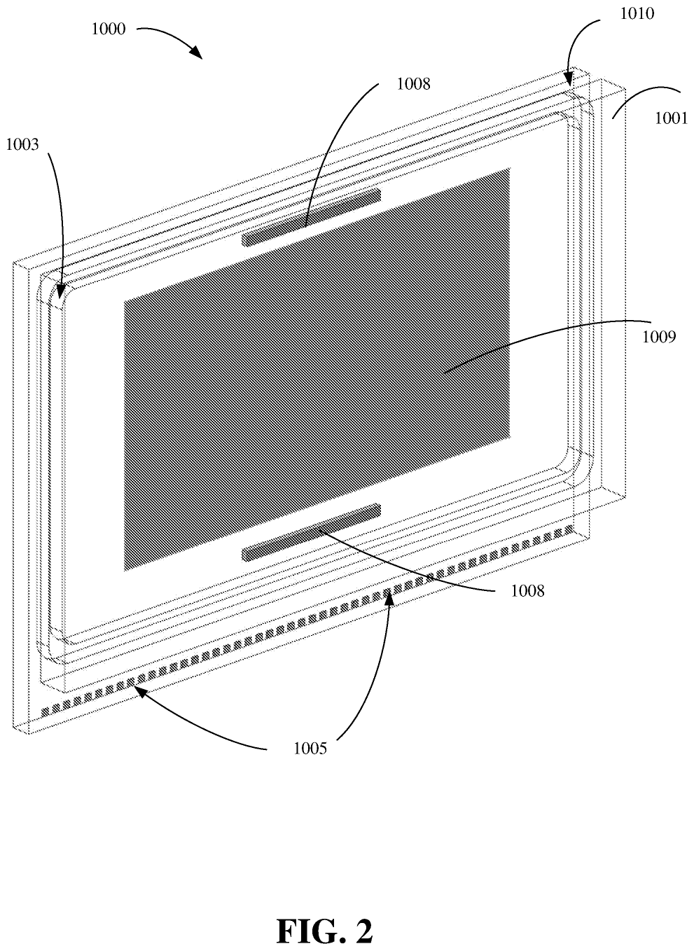

FIG. 1 is a side view of a first example of a MEMS package 1000 according to the teachings herein, and FIG. 2 is a perspective view of the MEMS package 1000 of FIG. 1. Generally, a cover 1001, a frame 1003, and a semiconductor substrate 1010 for a MEMS device (also referred to herein as a MEMS substrate 1010) are hermetically sealed with adhesion layers 1002, 1007 to form an encapsulated space for one or more electronic circuits. The encapsulated space may be filled with N₂ or an inert gas. The pressure within the encapsulated space may be below one atmosphere (atm).

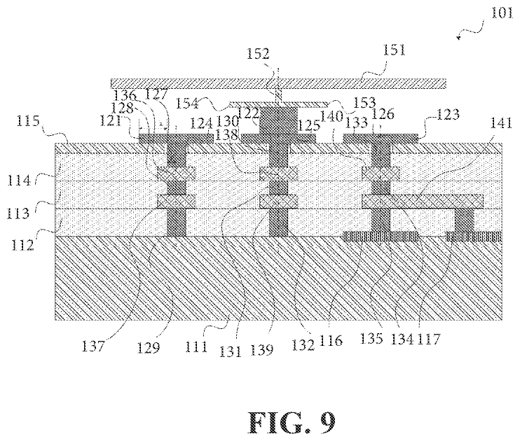

A MEMS device 1009 is formed over the MEMS substrate 1010, which may be a Complementary metal-oxide-semiconductor (CMOS) substrate supporting one or more driving circuits of the MEMS device 1009. The MEMS device 1009 may comprise an array of MEMS devices formed into a display. Due to the number of possible implementations, and the relative size of the individual components, the MEMS device 1009 is not shown in detail in FIG. 1. Examples of a MEMS device 1009 can be described with reference to the MEMS device 101 of FIG. 9.

The MEMS device 101 includes a substrate 111. At least one electronic circuit is formed on the substrate 111, which in this example is one or more transistors 116, 117. Inter-layer dielectrics 112, 113, 114 are formed on the substrate 111. Namely, the inter-layer dielectric 112 is formed on the substrate 111 and portions of the electronic circuits, here the transistors 116, 117. The inter-layer dielectric 113 is formed on the inter-layer dielectric 112, and the inter-layer dielectric 114 is formed on the inter-layer dielectric 113. More or fewer inter-layer dielectrics may be incorporated. An inter-layer dielectric may also be referred to herein as an insulating layer. An etch stop layer 115 formed on the (e.g., top) inter-layer dielectric 114 that is layered furthest from the substrate. At least the surface of the substrate may comprise aluminum nitride (AlN), alumina Al₂SO₃, Silicon or hafnium oxide HfO₂.

The MEMS device 101 has metal layers 136, 137, 138, 139, 140, 141 and electrodes 121, 122, 123 for electrical wiring between the inter-layer dielectrics 112, 113, 114. Also, the MEMS device 101 has vias 127, 128, 129, 130, 131, 131, 132, 133, 134, 135 connecting electrical wirings and electrodes. More generally, the MEMS device 101 can include one or more electrodes mounted on the etch stop layer 115 for electrical connection with the one or more electronic circuits of the MEMS device 101 through metal layers and vias insulated using the inter-layer dielectrics. The number of electrodes, metal layers, and vias of a MEMS device according to the teachings herein can vary based on the electronic circuits within the MEMS device 101 and their arrangements therein.

As shown in FIG. 1, the via 127 provides a conductive path through the inter-layer dielectric 114 from the electrode 121, which is formed on the etch stop layer 115, to the metal layer 136, which is formed on the inter-layer dielectric 114. The via 128 provides a conductive path through the inter-layer dielectric 113 from the metal layer 136, which is formed on the inter-layer dielectric 114, to the metal layer 137, which is formed on the inter-layer dielectric 112. The via 129 provides a conductive path through the inter-layer dielectric 112 from the metal layer 137, which is formed on the inter-layer dielectric 112, to the substrate 111. Through the vias 127, 128, 129 and the metal layers 136, 137, the electrode 121 may be electrically wired or connected to electronic circuits with contacts on the substrate 111, the inter-layer dielectric 113, and the inter-layer dielectric 114.

In a similar manner, the via 130 provides a conductive path through the inter-layer dielectric 114 from the electrode 122, which is formed on the etch stop layer 115, to the metal layer 138, which is formed on the inter-layer dielectric 114. The via 131 provides a conductive path through the inter-layer dielectric 113 from the metal layer 138, which is formed on the inter-layer dielectric 114, to the metal layer 139, which is formed on the inter-layer dielectric 112. The via 132 provides a conductive path through the inter-layer dielectric 112 from the metal layer 139, which is formed on the inter-layer dielectric 112, to the substrate 111. Through the vias 130, 131, 132 and the metal layers 138, 139, the electrode 122 may be electrically wired or connected to electronic circuits with contacts on the substrate 111, the inter-layer dielectric 113, and the inter-layer dielectric 114.

Connections of an electrode with an electronic circuit are shown in FIG. 1 with reference to the connection of the electrode 123 to contacts for one or more transistors 116, 117. The via 133 provides a conductive path through the inter-layer dielectric 114 from the electrode 123, which is formed on the etch stop layer 115, to the metal layer 140, which is formed on the inter-layer dielectric 114. The via 134 provides a conductive path through the inter-layer dielectric 113 from the metal layer 140, which is formed on the inter-layer dielectric 114, to the metal layer 141, which is formed on the inter-layer dielectric 112. The vias 135 provide respective conductive paths through the inter-layer dielectric 112 from the metal layer 141, which is formed on the inter-layer dielectric 112, to the contacts of the one or more transistors 116, 117. Through the vias 133, 134, 135 and the metal layers 140, 141, the electrode 123 may also be electrically wired or connected to electronic circuits with contacts on the inter-layer dielectric 113, and the inter-layer dielectric 114.

Further, the MEMS device 101 has a hinge 152 formed on the electrode 122 directly or on an additional conductive support structure mounted on the electrode 122, where the conductive support as shown in each of the figures by example may be formed of the same material as the electrode 122. The MEMS device 101 has a mirror element 151 formed on the upper side of the hinge 152. In this example, the mirror element 151 is a movable element that may be incorporated into the MEMS device. Meanwhile, a mechanical stopper 153, 154 is formed at the bottom of the hinge 152. The mechanical stopper 153, 154 as shown is a single piece formed of the same material as the hinge 152 that extends in parallel with the default or unexcited position of the mirror element 151, which is in turn in parallel with a mounting surface of the substrate 111 and its layers.

The substrate 111 may be composed of single crystal silicon, or some other substrate material. The transistors 116 and 117 are CMOS transistors in this example, but other electronic circuits are possible. The inter-layer dielectrics 112, 113, 114 are interlayer insulating films or layers including silicon dioxide (SiO₂) or another appropriate insulating material.

The metal layers 136, 137, 138, 139, 140, 141 are made of, for example, aluminum (Al), copper (Cu), or an aluminum copper alloy (Al—Cu).

The electrodes 121, 122, 123 are made of tungsten (W) or the same material as the vias. Each of the vias 127, 128, 129, 130, 131, 131, 132, 133, 134, 135 is formed as a through-hole that extends through at least one layer of the MEMS device 101 and is filled with a conductive material, W in this example. In addition, gaps 124, 125, and 126 may be formed between the vias 127, 130, 133 and the etch stop layer 115 during manufacturing that result in problems in the manufacturing method because a subsequently-used etchant may penetrate these gaps and damage the structures, to mitigate this problem, and assuming that the radius of the via 127 is r, it is desirable that the relationship of the distance x over which the electrode 121 covers the etch stop layer 115 is more than twice r. This same relationship between the radius r of a via through an etch stop layer and the length or distance x of an electrode mounted on the etch stop layer is desirable for each electrode mounted on the etch stop layer.

In a structure herein where an electrode, such as the electrode 122, is mounted on the etch stop layer, such as the etch stop layer 115, the relationship is described above as the distance x over which the electrode covers the etch stop layer is more than twice r. The electrode may be described as having a length, a size or a dimension (e.g., a length, a width, or a radius) along the surface upon which it is mounted that is at least twice the radius of the via with which it is electrically connected.

That is, for example, is desirable that the electrodes 121, 122, 123 covering the etch stop layer 115 have a size that is twice or more the radius of the via connected to each. This prevents the vapor etchant from (i) penetrating the electrodes 121, 122, 123 and the etch stop layer 115 and (ii) eroding the inter-layer dielectric 114 through the gaps 124, 125, 126.

The hinge 152 is a deformable member that supports the mirror element 151. The hinge 152 is made of a material such as amorphous silicon or poly-silicon, for example.

The mirror element 151 is a member capable of reflecting light from light sources. The mirror element 151 has a support layer composed of titanium (Ti), W, or the like, and a mirror layer composed of a material with good reflectivity, such as Al, gold (Au), or silver (Ag), or any combination thereof.

The mirror element 151 is electrostatically attracted to the electrode 123, and the hinge 152 tilts due to deformation into an ON position of the mirror element 151. This may result from applying a voltage between the movable element (e.g., the mirror element 151) and the electrode 123 by the electronic circuit formed on the substrate 111 (e.g., the transistors 116, 117) and a voltage source generally mounted elsewhere. The voltage causes the attractive force. The mirror element 151 is prevented from contact with the electrode 123, which is not covered with an insulating layer, by contacting the stopper 153. That is, the mechanical stopper 153, 154 is mounted at a height above the electrodes 121, 123 and has a size (e.g., a length) sufficient to prevent deformation of the hinge 152 from causing the mirror element 151 to contact the electrode 123. For example, the length of the mechanical stopper 153, 154 allows contact with the mirror element 151 when the mirror element 151 tilts to prevent the mirror element 151 from contacting another other portion of the MEMS device. Deformation of the hinge 152 is prevented from causing the mirror element 151 to contact the electrode 123. Thus, it is possible to prevent an electrical short circuit. Because the mechanical stopper 153, 154 is formed of the same material as the hinge 152 in this example, it may also deform slightly, but this deformation may be ignored, or may be considered in determining the length and mounting height of the mechanical stopper 153, 154. Absent the application of a voltage, the hinge 152 returns to the OFF position of the mirror element 151 shown in FIG. 9.

FIG. 9 shows a single MEMS device 101 with a single movable element as an example of a MEMS device that may be enclosed within the MEMS package 1000, where the substrate 111 corresponds to the substrate 1010 of FIG. 1. However, the MEMS devices described herein may include multiple movable elements. Where the movable element is a mirror such that the MEMS device is used in a display, for example, the MEMS device 1009 may include many (e.g., millions of) mirrors and their electrical connections similar to the structure of the MEMS device 101 arranged in an array on one or more interconnected substrates 111.

Further, different embodiments of the MEMS device 101 may be incorporated into the MEMS device 1009. For example, the etch stop layer 115 may alternatively be formed above the electrodes 121, 122, 123, instead of below the electrodes 121, 122, 123. This allows the mechanical stoppers 153, 154 in FIG. 9 to optionally be omitted because inclination of the mirror element 151 resulting from deformation of the hinge 152 could be restricted by contact with the etch stop layer 115, which is an insulating film composed of AlN or Aluminum oxide (Al₂O₃) that can prevent an electrical short circuit. Where mechanical stoppers are included, they may have a different form, number, and arrangement than the mechanical stoppers 153, 154. For example, one or more, stoppers may extend perpendicularly from a top surface of the substrate 111 through the etch stop layer 115 to a height sufficient to prevent contact of the mirror element 151 with an electrode, the etch stop layer 115, or both, upon deformation of the hinge 152.

The MEMS device 1009 may comprise an array of MEMS devices all having the same structure or having a combination of different structures as described with regards to the MEMS device 101.

Referring again to FIGS. 1 and 2, the frame 1003 comprises at least one wall surrounding the MEMS device 1009 and sealed to the MEMS substrate 1010 of the MEMS device 1009 by an adhesion layer 1007. One or more strips of moisture-absorbing material, herein referred to as getters 1008, may be deposited on the surface of the MEMS substrate 1010. The getters 1008 may be spaced apart from the MEMS device 1009. The moisture-absorbing material may comprise at wherein the moisture absorbing material comprises at least one of Apatite, Zeolite, Calcium oxide, Calcium carbonate, Titania, Zirconium dioxide, Yttrium oxide, metal-organic frameworks, or Silica gel.

As can be seen in the example of FIG. 2, the frame 1003 may comprise a rectangular tube. The frame 1003 may comprise a square tube, a cylinder, or any other shape having a size (e.g., a width) sufficient to surround the MEMS device 1009 and, where present, the getters 1008. The frame 1003 may be, for example about 20 mm×16 mm. The wall(s) of the frame 1003 are at least high enough so that no component of the MEMS device 1009 contacts the cover 1001 during any stage of operation of the MEMS device 1009. For example, where the MEMS device comprises an array of MEMS devices 101, the wall(s) of the frame 1003 are high enough so that the edge of a mirror element 151 does not contact the cover 1001, when the mirror element 151 is inclined into the ON state or position. The height may be at least 5 microns, and is more preferably over 10 microns.

The cover 1001 may be made of a transparent or translucent material. In some implementations, the cover 1001 comprises glass, and may be tempered glass. The glass may absorb ultraviolet (UV) light. The glass may be coated with an anti-reflection layer having a minimum reflection at least between 400 nm and 700 nm wavelength. The glass may be coated with a reflective layer for infra-red (IR) and UV light. The cover 1001 may be a planar sheet. The cover 1001 may be about 1 mm in thickness in some implementations. The cover 1001 can have a shape conforming to the shape of the frame 1003. For example, the cover 1001 may have a rectangular shape, a square shape, a circular shape, or any other shape. The cover 1001 may have a size sufficient to cover the entirety of the top opening of the frame 1003 and provide a lip for sealing with the frame 1003 using the adhesion layer 1002. The cover 1001 may have outer dimensions larger than the outer dimensions of the frame 1003. The only requirements for the material of the frame 1003 are that it be strong enough to support the cover 1001 and have a width sufficient to provide a sealing surface for the cover 1001 and the MEMS substrate 1010. However, it is desirable that the frame 1003 be made of a material that has a similar thermal expansion coefficient as the cover 1001 in order to form and maintain a tight seal. Accordingly, in an example where the cover 1001 is formed of glass, the frame 1003 may be formed of a metal or metal alloy such as Kovar. The frame 1003 can also comprise glass or steel containing nickel whose ratio is more than 20% in weight or some combination of these materials. With regards to the width of the frame 1003, it should at least be as wide as the solder to be applied as described below, which in an example is about 200 to 300 microns.

Multiple pads 1005 of the electronic (e.g., CMOS) circuits of the MEMS device 1009 are located outside of the frame 1003. Hence, the pads 1005 are located outside of the seal. While shown directly secured to the MEMS substrate 1010 in FIGS. 1 and 2, the pads 1005 may be connected by a socket or directly soldered to a PC board or a flexible PC board with solder bumps 1004. The solder bumps 1004, and those described below, may be formed of an alloy including at least one of Au, Sn, InSn or In. The multiple pads 1005 may be coupled to traces mounted on the MEMS substrate 1010 and to voltage and/or current sources external of the MEMS package 1000 for controlling the electronic circuits. For example, where the MEMS device 1009 is a MEMS array comprising the MEMS devices 101, the traces may form an array on the surface of the MEMS substrate for signaling Lite transistors 116, 117 of respective ones of the MEMS devices 101. The multiple pads 1005 may be coupled to the traces and to a voltage source external of the MEMS package 1000 to apply a voltage across the mirror element 151 and an electrode.

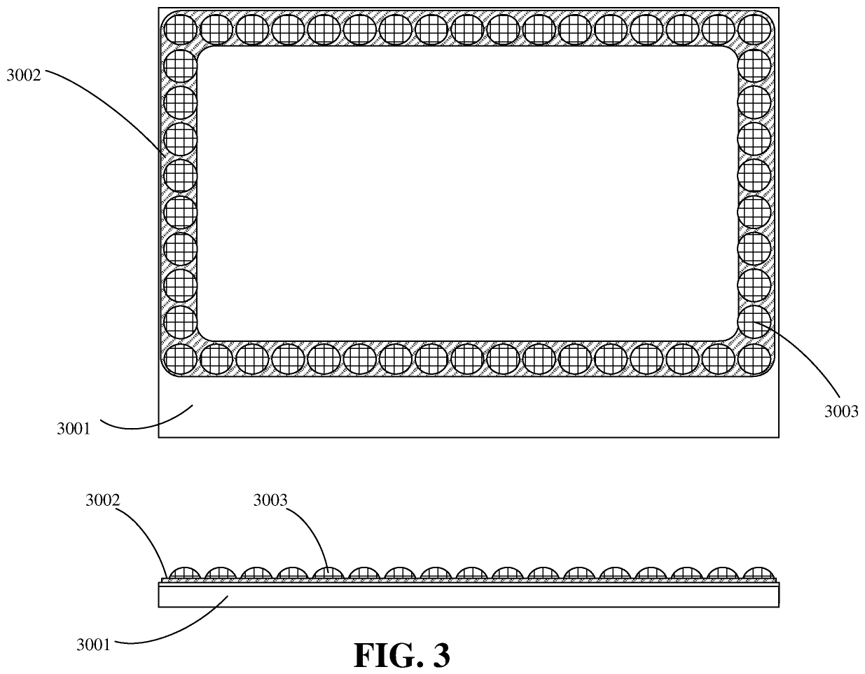

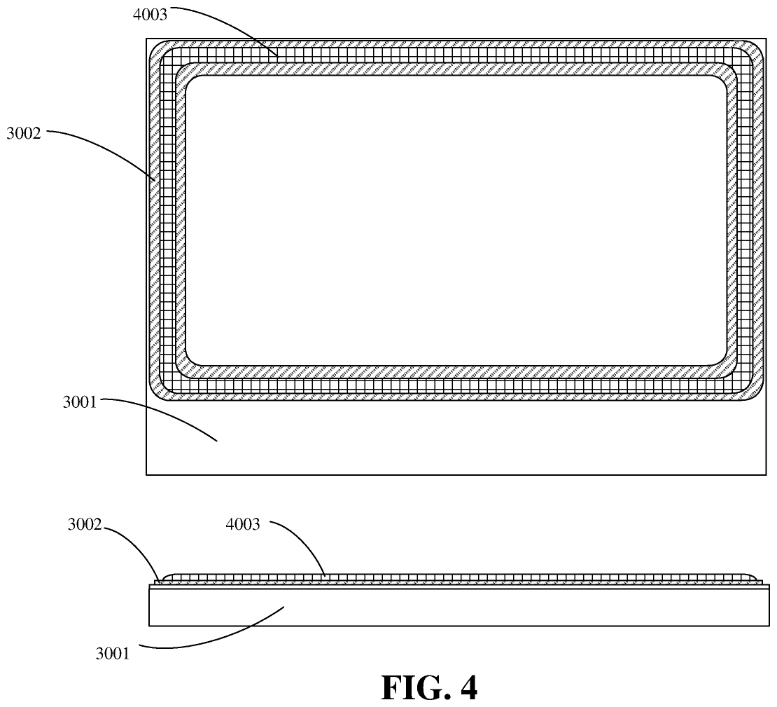

Referring now to FIGS. 3 and 4, certain manufacturing steps of the MEMS package according to the teachings herein are illustrated. Specifically, formation of the adhesion layer 1007 is illustrated. Each of Lite adhesion layers 1002, 1007 comprises at least three layers including at least two metallic adhesion layers sandwiching a solder layer.

FIG. 3 is an illustration of the results of a soldering step of manufacturing a MEMS package, such as the MEMS package 1000. Specifically, a metallic adhesion layer 3002 is applied to a MEMS substrate 3001 for a MEMS device to be packaged. The metallic adhesion layer 3002 conforms to the shape of the wall(s) of the frame, such as the frame 1003. In this example, the metallic adhesion layer 3002 is applied to form the outline of a rectangle. The metallic adhesion layer 3002 may be applied by chemical metallization or vacuum evaporation or sputtering. The thickness of the metallic adhesion layer 3002 may be under 5 microns (such as 1 to 2 microns). Thereafter, the soldering step applies solder balls to form solder bumps 3003 on the surface of the metallic adhesion layer 3002. The solder balls may be applied, for example, by spray from an ink-jet printer. The resulting solder bumps 3003 may be from about 50 to 100 microns thick in this example. Other thicknesses are possible.

FIG. 4 is an illustration of the results of a reflow step of manufacturing the MEMS package. The reflow step occurs after the soldering step. Namely, the solder humps 3003 of FIG. 3 are reflowed by heating (e.g., melted) to create a solder layer 4003. The solder layer 4003 is desirably flat and continuous. In one example, the solder layer 4003 is over 5 microns in thickness. In other examples, the solder layer 4003 is thicker, such as several tens of microns in thickness. After reflow, for example, the solder layer 4003 may be between 10 to 30 microns.

After the reflow step, another metallic adhesion layer may be applied to the solder layer 4003 and any exposed portions of the underlying metallic adhesion layer 3002. The frame, such as the frame 1003, can then be mounted atop the relatively thick adhesion layer to seal the frame to the MEMS substrate 3001. The adhesion layer that seals the cover to the frame may be formed in the same manner. For example, the adhesion layer 1002 may be formed atop the top-facing edge of the frame 1003 (i.e., the edge facing away from the MEMS substrate 1010) by applying a first metallic adhesion layer in the same manner as the metallic adhesion layer 3002, followed by the soldering step as described with regards to FIG. 3. The resulting solder bumps may be reflowed to form the soldering layer of the adhesion layer 1002. Finally, a second metallic adhesion layer may be applied to finalize the adhesion layer 1002. The cover may then be mounted atop the relatively thick adhesion layer to secure the cover to the frame.

In some cases, each of the first metallic layer and the second metallic layer of the adhesion layers 1002, 1007 may themselves be formed of separate layers. Regardless of how many layers are included, the materials of the metallic adhesion layers and the solder layer forming adhesion layers 1002, 1007 should be selected so that they will securely adhere to the materials they will contact. The solder can be a gold alloy such as eutectic gold tin (AuSn). Each of the first metallic layer and the second metallic layer of the adhesion layers 1002, 1007 may be made of Ti, nickel (Ni), platinum (Pt), Au, chromium (Cr), or any combination of these materials. In an implementation, the first metallic layer, the second metallic layer, or both, may be formed of two layers or three layers. For example, when formed of two layers, the first layer may comprise Cr, and the second layer may comprise Au. The first metallic layer, the second metallic layer, or both, so formed may be referred to herein as being made of Cr/Au.

When the adhesion layer 1002 is formed of three layers, a first layer may be formed of a material having a good adhesion to the material of the cover 1001 where the cover 1001 is made of glass, such as Ti, a third layer may be formed of a material having a good adhesion to the material of the solder layer 4003, such as Au, and the second layer may be formed of a material having a good adhesion to the material(s) of the first and third layers, such as Pt. The first metallic layer, the second metallic layer, or both, so formed may be referred to herein as being made of Ti/Pt/Au.

While the materials and structure of the adhesion layer 1007 may be the same as the materials and structure of the adhesion layer 1002, the materials of the adhesion layer 1007 may differ from the adhesion layer 1002 in some packages. The adhesion layer 1007 may differ due to the material that is on the surface of the MEMS substrate 1010, 3001. For example, where the adhesion layer 1007 is formed on three layers, the layer adjacent to the MEMS substrate 1010, 3001 may differ. If the surface of MEMS substrate 1010, 3001 is AlN, Al₂O₃, or Silicon, the adjacent layer can be formed of Ti. The first metallic layer of the adhesion layer 1007, the second metallic layer of the adhesion layer 1007, or both, may be made of Ti/Pt/Au, which is the same as the layers of the three-layer example of the adhesion layer 1002 above.

The structure described for the MEMS package 1000 uses a relatively thick solder layer on top of a metallic adhesion layer, which is sandwiched by another metallic adhesion layer. This structure enables a hermetic seal of relatively rough surfaces, which can be manufactured inexpensively. This structure also removes VOC through the inclusion of the at least two metallic adhesion layers.

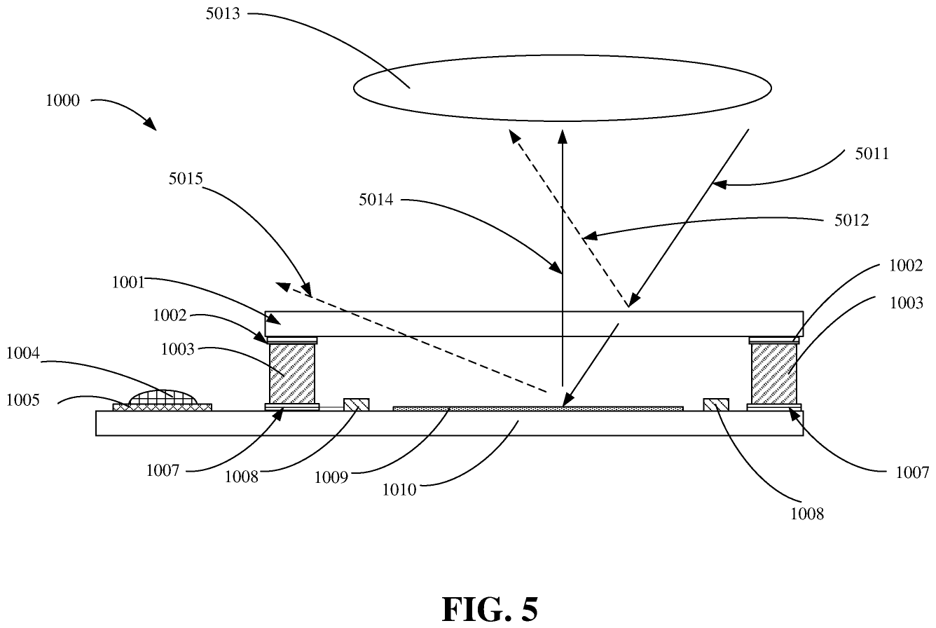

While the structure for the MEMS package 1000 has significant benefits, alternative structures according to the teachings herein are possible. For example, an alternative structure may be described with initial reference to FIG. 5. FIG. 5 shows the MEMS package 1000 used as a MEMS display projecting am image to a screen through a projection lens 5013. In this arrangement, the surface of the cover 1001 is parallel to the substrate 1010.

An incident light beam 5011 is projected onto the surface of the MEMS device 1009 mounted within the MEMS package 1010. In this example, the MEMS device 1009 comprises a pixel array. The resulting reflected image (e.g., from switching of the mirror elements 151) is conveyed along the direction of the arrow 5014. The MEMS device 1009 also deflects a portion of the incident light beam 5011 in the direction of the arrow 5015. In order to reach the surface of the MEMS device 1009, the incident light beam 5011 also projects onto the cover 1001. The cover 1001, although it can be transparent, will reflect some fraction of the incident light generally in the direction of the arrow 5012. This can occur even when the surface is coated with one or more anti-reflection layers. For example, the ratio of reflection may be in the range of 0.3% to 0.6% even with an anti-reflection coating applied. This degrades the contrast of the image. Some manufacturers claim a contrast ratio of 10,000 to 1 or even 20,000 to 1. If the entirety of the 0.3% incident light that is reflected enters the projection lens 5013, the contrast ratio can be reduced down to 300 to 1.

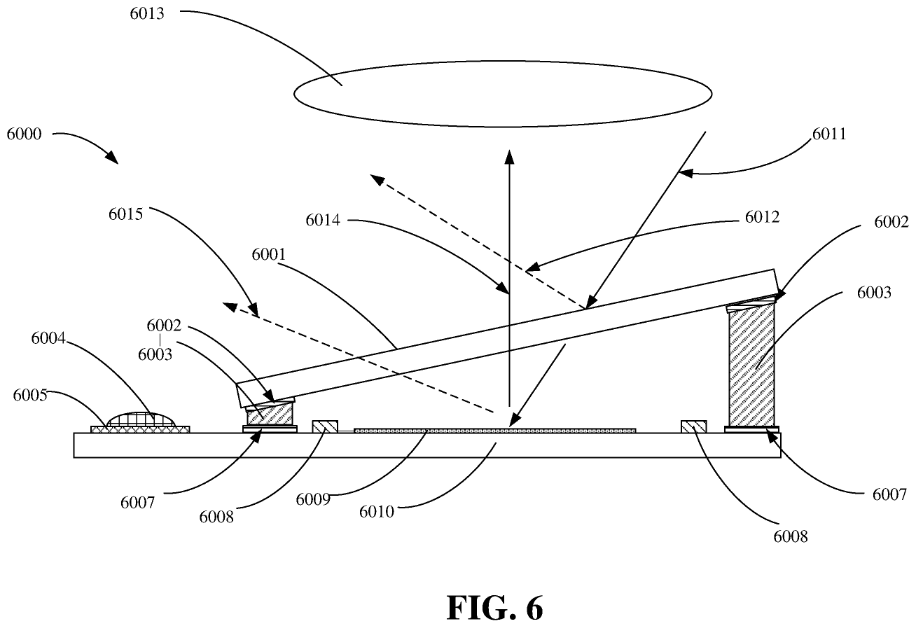

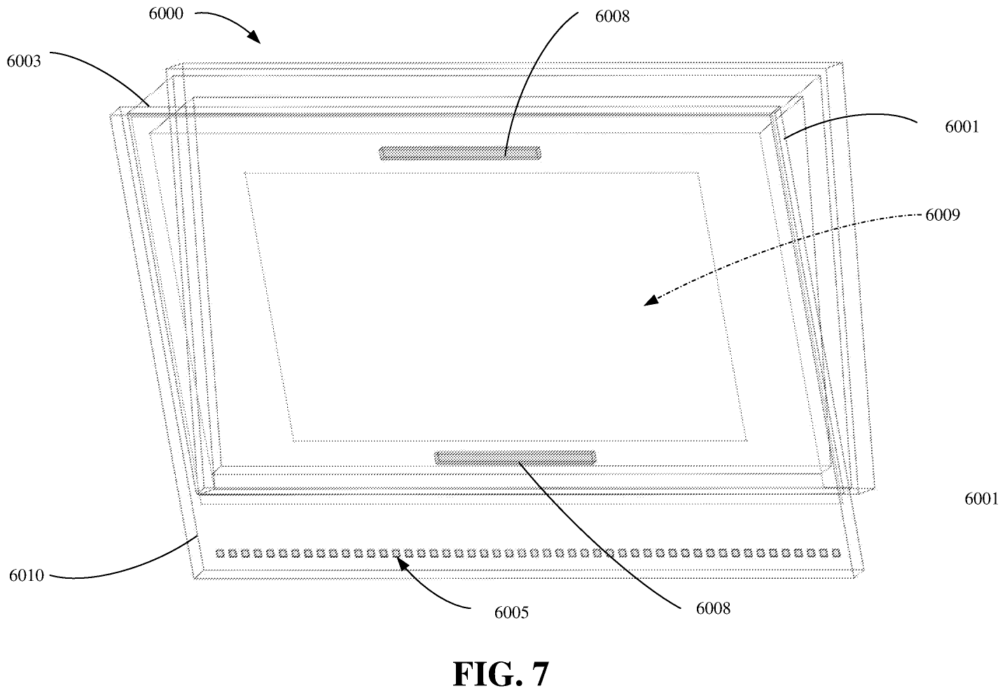

FIG. 6 is a side view of a second example of a MEMS package 6000 according to the teachings herein that can reduce unwanted light reflection by a cover 6001, and FIG. 7 is a perspective view of the MEMS package 6000 of FIG. 6. The MEMS package 6000 may be substantially similar in structure to the MEMS package 1000.

That is, a cover 6001, a frame 6003, and a semiconductor substrate 6010 for a MEMS device (also referred to herein as a MEMS substrate 6010) are hermetically sealed with adhesion layers 6002, 6007. The cover 6001 may comprise the same structure and materials as described with regards to the cover 1001, and the adhesion layers 6002, 6007 may comprise the same structure and materials as described with regards to the adhesion layers 1002, 1007. The frame 6003 may comprise the same materials as and a substantially similar structure to the frame 1003 as discussed in additional detail below.

A MEMS device 6009 is formed over the MEMS substrate 6010, which may be a CMOS substrate supporting one or more driving circuits of the MEMS device 6009. The MEMS substrate 6010 may comprise the same structure and materials as described with regards to the MEMS substrate 1010. The MEMS device 6009 may comprise one or an array of MEMS devices such as the examples described above with reference to the MEMS device 101 of FIG. 9 and the MEMS device 1009 of FIG. 1.

One or more strips of moisture-absorbing material, herein referred to as getters 6008, may be deposited on the surface of the MEMS substrate 6010 within the frame 6003 so that the getters 6008 are hermetically sealed with the MEMS device 6009. The getters 6008 may comprise the same structure and materials as described with regards to the getters 1008.

Multiple pads 6005 of the electronic (e.g., CMOS) circuits of the MEMS device 6009 are directly secured to the MEMS substrate 6010 outside of the frame 6003 using respective solder bumps 6004. The pads 6005 and the solder bumps 6004 may comprise the same structure and materials as described with regards to the pads 1005 and the solder bumps 1004, respectively. That is, for example, the pads 6005 may be connected by a socket or directly soldered to a PC board or a flexible PC board with the solder bumps 6004. The multiple pads 6005 may be coupled to traces mounted on the MEMS substrate 6010 and to voltage and/or current sources external of the MEMS package 6000 for controlling the electronic circuits in a like manner as described with regards to the MEMS package 1000.

As with the frame 1003, the frame 6003 comprises at least one wall surrounding the MEMS device 6009 and optionally the getters 6008 that is sealed to the MEMS substrate 6010 of the MEMS device 6009 by the adhesion layer 6007 and to the cover 6001 by the adhesion layer 6002. The frame 6003 may comprise a square tube, a cylinder, or any other shape having a size (e.g., a width) sufficient to surround the MEMS device 6009 and, where present, the getters 6008. The wall(s) of the frame 6003 are at least high enough so that no component of the MEMS device 6009 contacts the cover 6001 during any stage of operation of the MEMS device 6009. For example, where the MEMS device comprises an array of MEMS devices 101 as described in FIG. 9, the wall(s) of the frame 6003 have a minimum height such that the edge of a mirror element 151 does not contact the cover 6001, when the mirror element 151 is inclined into the ON state or position.

Unlike the frame 1003, the frame 6003 does not extend to the same height above the surface of the MEMS substrate such that the cover is mounted parallel to the surface. This difference can be seen by referring again to FIGS. 6 and 7, where an example of the frame 6003 of the MEMS package 6000 comprises a rectangular tube. The rectangular tube includes a first edge at a minimum height, an opposing second edge at a maximum height, and sloped opposing edges extending between the first edge and the second edge.

Like shown in FIG. 5, the MEMS package 6000 may be used as a MEMS display projecting am image to a screen through a projection lens 6013. An incident light beam 6011 is projected onto the surface of the MEMS device 6009 mounted within the MEMS package 6010. The MEMS device 6009 comprises a pixel array in this example. For example, the pixel array may comprise multiple mirror elements 151 and their associated electronics as described with regards to the MEMS device 101 of FIG. 9. A reflected image resulting from switching of the mirror elements 151 between ON and OFF positions is conveyed along the direction of the arrow 6014. The MEMS device 6009 still deflects a portion of the incident light beam 6011 in the direction of the arrow 6015.

In order to reach the surface of the MEMS device 6009, the incident light beam 6011 also projects onto the cover 6001. The cover 6001, like the cover 1001, will reflect some fraction of the incident light generally in the direction of the arrow 6012. In this example, however, the direction of the arrow 6012 is different from the direction of the arrow 5012 in FIG. 5 due to the angle (e.g., slope, tilt, etc.) of the cover 6001. Specifically, the angle of inclination of the cover 6001 causes the reflection light to be directed further away from the projection lens 6013. That is, the majority of the reflected light is directed away from the projection lens 6013. This improves the contrast ratio as compared to the MEMS package 1000 in some implementations.

The angle of inclination or tilt of the cover 6001 above parallel, and hence the measurements of the frame 6003, can depend on the structure of the MEMS device 6009. For example, in an implementation of the MEMS device 6009 using an array of MEMS devices 101, the cover 6001 may be tilted to as much as the tilt angle of the mirror elements 151, but in the opposite direction. Referring to FIGS. 6 and 9, if the MEMS devices 101 oriented as shown in FIG. 9 are mounted within the MEMS package 6000 in the orientation shown in FIG. 6, the ON position of the mirror element 151 is where the mirror element 151 is in contact with one of the stoppers 153, 154. In this example, the tilt of the mirror element 151 extends downward towards the right side of FIG. 6 to contact the stopper 153 in the ON position. Accordingly, the tilt of the cover 6001 is to the left side of FIG. 6. Desirably, the cover is tilted more than 5 degrees with respect to the surface of the substrate.

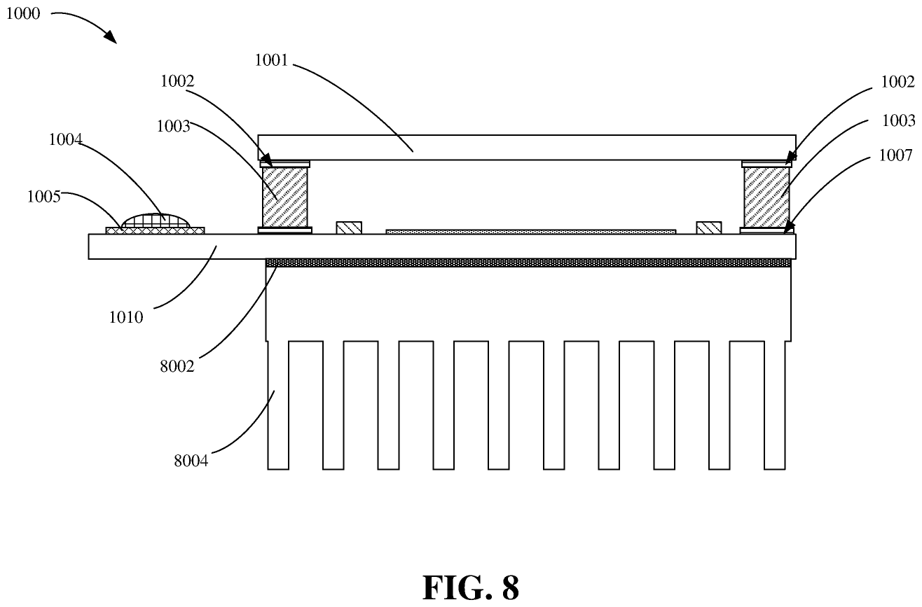

FIG. 8 illustrates another variation of the MEMS packages according to the teachings herein. Conventional packages for MEMS devices may have difficulty with cooling. For example, such a package often includes a ceramic substrate for the connection between a silicon MEMS chip and a printed circuit board (PCB) for control of the electronics of the MEMS chip. Ceramic substrates with internal circuits are often costly. Further, the thermal conductivity is not as good as that of metal. The MEMS packages described herein can avoid the cost and improve thermal conductivity over such designs.

As shown in the example of FIG. 8, a thermally-conductive adhesive 8002 secures a heat sink 8004 to the MEMS substrate 1010. This is a direct attachment to the backside of the MEMS substrate 1010. The backside may also be referred to as the side opposing the top (e.g., mounting) surface or the bottom surface of the MEMS substrate 1010. The top surface is the surface of the MEMS substrate 1010 facing the cover 1001. Because the cover 1001 and the frame 1003 are directly sealed to the MEMS substrate 1010, the direct attachment of the heat sink 8004 is possible because the pads 1005 for electrical connection are exposed to the outside of the hermetic seal. This structure enables the direct contact of the MEMS device 1009 to the heat sink 8004. This ensures a higher heat flow than a package having a ceramic substrate.

Although FIG. 8 shows the heat sink 8004 attached to the MEMS substrate 1010 as part of the MEMS package 1000, the heat sink 8004 may be attached to any example of a MEMS package according to the teachings herein. For example, the thermally-conductive adhesive 8002 may secure the heat sink 8004 to the MEMS substrate 6010.

Although the present invention has been described in terms of certain embodiments, it is to be understood that such disclosure is not to be interpreted as limiting. Various alterations and modifications will become apparent to those skilled in the art after reading the disclosure. Accordingly, it is intended that the appended claims be interpreted as covering all alternations and modifications that fall within the scope thereof.

1. A Micro-Electro-Mechanical Systems (MEMS) package, comprising:
a MEMS device including a substrate on which an electronic circuit is formed;
a frame surrounding the electronic circuit and affixed to a surface of the substrate with a frame adhering layer; and
a cover affixed to the frame with a cover adhering layer, the cover encapsulating the electronic circuit within the frame, wherein each of the frame adhering layer and the cover adhering layer comprises a solder layer between at least two metallic adhesion layers, the solder layer comprising reflowed solder balls.

2. The MEMS package of claim 1, further comprising:
a layer of moisture absorbing material mounted on the substrate and encapsulated with the electronic circuit.

3. The MEMS package of claim 1, further comprising:
pads electrically connected to the electronic circuit and mounted outside of the frame.

4. The MEMS package of claim 1, wherein the MEMS device comprises an array of MEMS devices, each MEMS device comprising:
an electronic circuit on the substrate;
an electrode electrically connected to the electronic circuit; and
a movable element that is controlled by applying a voltage between the electrode and the movable element.

5. The MEMS package of claim 1, wherein the cover comprises glass that absorbs ultraviolet light.

6. The MEMS package of claim 1, wherein the frame comprises glass, Kovar, steel containing nickel whose ratio is more than 20% in weight, or any combination thereof.

7. The MEMS package of claim 1, wherein at least the surface of the substrate comprises AlN, Al₂SO₃, Silicon, or HfO₂, or any combination thereof.

8. The MEMS package of claim 1, wherein each of the metallic adhesion layers comprises Ti, Ni, Pt, Au, Cr, or some combination thereof.

9. The MEMS package of claim 8, wherein at least some of the metallic adhesion layers comprise three layers, a first layer of Ti, a second layer of Pt, and a third layer of Au.

10. The MEMS package of claim 1, wherein the solder layer is thicker than 5 microns.

11. The MEMS package of claim 10, wherein the solder layer is formed of an alloy including at least one of Au, Sn, InSn or In.

12. The MEMS package of claim 1, wherein the solder layer is formed by spraying solder balls and subsequently reflowing the solder balls.

13. The MEMS package of claim 12, wherein a height of the solder balls is larger than 50 microns.

14. The MEMS package of claim 1, wherein the cover comprises glass coated with an anti-reflection layer having a minimum reflection at least between 400 nm and 700 nm wavelength.

15. The MEMS package of claim 1, wherein the cover comprises glass coated with a reflective layer for infra-red and ultraviolet light.

16. The MEMS package of claim 2, wherein the moisture absorbing material comprises at least one of Apatite, Zeolite, Calcium oxide, Calcium carbonate, Titania, Zirconium dioxide, Yttrium oxide, metal-organic frameworks, or Silica gel.

17. The MEMS package of claim 1, wherein the cover, the frame, and the substrate form an encapsulated space filled with N₂, an inert gas, or both.

18. The MEMS package of claim 17, wherein a pressure within the encapsulated space is below 1 atm.

19. The MEMS package of claim 1, further comprising:
a heat sink affixed to a bottom surface of the substrate.

20. The MEMS package of claim 1, wherein the cover is tilted more than 5 degrees with respect to the surface of the substrate.
